(19) United States
(12) Patent Application Publication
(10) Pub. No.: US 2026/0353903 A1
(43) Pub. Date: Nov. 5, 2026

(54) LED FILAMENT FOR EMITTING WHITE LIGHT AND COLORED LIGHT

(71) Applicant: SIGNIFY HOLDING B.V., EINDHOVEN (NL)

(72) Inventors: TIES VAN BOMMEL, HORST (NL); ERIK MALLENS, DENBOSCH (NL)

(21) Appl. No.: 19/487,027

(22) PCT Filed: May 21, 2024
(86) PCT No.: PCT/EP2024/063956

§ 371 Date: Nov. 24, 2025

(30) Foreign Application Priority Data
Jun. 1, 2023 (EP) 23176656.9

(51) Int. Cl. H10H 29/80; F21K 9/232; H10H 29/852

(52) U.S. Cl. CPC H10H 29/962; F21K 9/232; H10H 29/852

(57) ABSTRACT

The invention relates to a LED filament (1) and to a LED filament lamp (3) comprising the LED filament (1), wherein the LED filament (1) is configured to emit white or colored light. The LED filament (1) comprises at least ten LEDs (9¹-9ⁿ) arranged on an elongated carrier (2). The LEDs (9¹-9ⁿ) may be different colored LEDs (9¹-9ⁿ) where the LEDs comprise at least five different dominant peak wavelengths. The LEDs (9¹-9ⁿ) are alternately positioned between each other along the carrier (2). The LED filament (1) comprises a plurality of first blue LEDs (9¹) configured to emit first light having a first dominant peak wavelength, 1, and a plurality of first and second green-yellow LEDs (9², 9³) configured to emit second light having second and third dominant peak wavelengths #2, #3, respectively, and a plurality of first red-orange LEDs (9⁴) configured to emit fourth light having a fourth dominant peak wavelength #4. The LED filament (1) furthermore comprises one or both of at least one third green-yellow LED (9 #) configured to emit fifth light having a fifth dominant peak wavelength, #5, and at least one second red-orange LED (9 #) configured to emit sixth light having a sixth dominant peak wavelength, #6. The difference between each of the dominant peak wavelengths is at least 20 nm. Further LEDs (9¹-9ⁿ) comprising different dominant peak wavelengths may be added.

### FIELD OF THE INVENTION

The invention relates to a LED filament and to a LED filament lamp comprising the LED filament. The invention further relates to the LED filament having a controllable white or colored light.

### BACKGROUND OF THE INVENTION

A trend in lighting is LED filament lamps designed to resemble a traditional incandescent light bulb with a visible filament for aesthetic and light distribution purposes, but with the high efficiency of light-emitting diodes, LEDs.

It is well-known that a high-quality white light emitting from a LED filament lamp is provided by a LED filament emitting a phosphor-converted light, pc-light. However, the yellow/orange appearance of pc-LED filaments is undesired, and the pc-LED filaments are not configured to individually provide red, green and blue colored light, e.g., due to cross-talk of the blue light with the phosphor. The pc-LED filaments are therefore not suitable for applications in which such crosstalk is undesired.

On the other hand, a RGB LED filament can also provide white light, and be configured to individually provide red, green and blue colored light. However, RGB LED filaments do not provide high quality white light.

WO 2021/094257 A 1 discloses a LED filament for a LED filament lamp, wherein the LED filament is configured to emit a high-quality white light and provide red, green and blue colored light being individually controlled. The LED filament comprises a first linear array of white LEDs configured to emit phosphor-converted white light. The white LEDs is arranged on a first surface of a carrier including only white LEDs. The LED filament also comprises a second linear array of colored LEDs configured to emit color controllable light, wherein the colored LEDs are arranged on a second surface of the carrier, opposite to said first surface. The LEDs are based on UV LEDs which emit UV light and/or blue LEDs which emit blue light. The UV LEDs and/or blue LEDs are covered by a first encapsulant which comprises a luminescent material which is configured to at least partly convert the UV light and/or the blue light into phosphor-converted white light.

It is thus desired to provide a phosphor-free LED filament with which a yellow/orange appearance similar to that of pc-LED filaments is avoided, and with which unwanted cross-talk of LED light and phosphor is also avoided. This means that only direct emitting LEDs are used in the filament providing a white-silver-looking appearance in the OFF state of the filament. It better resembles a filament of an incandescent lamp which is desired. The drawback is that direct emitting LEDs provide only narrow band light. But this is compensated by using the combination of the different sets of LEDs.

It is furthermore desired to provide a phosphor-free LED filament capable of emitting a high-quality white light, preferably extreme warm white light. The object of the present invention is furthermore to provide a LED filament capable of emitting high-quality colored light, wherein the colored light can be individually controlled.

### SUMMARY OF THE INVENTION

It is an object of the present invention to provide a phosphor-free LED filament capable of emitting a high-quality white light, preferably extreme warm white light. The object of the present invention is furthermore to provide a LED filament capable of emitting high-quality colored light, wherein the colored light can be individually controlled.

It is a further object of the present invention to provide a phosphor-free LED filament with which a yellow/orange appearance similar to that of pc-LED filaments is avoided, and with which unwanted crosstalk of LED light and phosphor is also avoided.

These and other objects are achieved by providing a LED filament configured to emit LED filament light, wherein the LED filament comprises at least ten LEDs arranged on an elongated carrier, wherein the LED filament comprises:
a plurality of first blue LEDs configured to emit first light having a first dominant peak wavelength, λ1, in a wavelength range from 430 nm to 495 nm;
a plurality of first green-yellow LEDs configured to emit second light having a second dominant peak wavelength, λ2, in a wavelength range from 500 nm to 595 nm, the second dominant peak wavelength, λ2, being different from first dominant peak wavelength, λ1, wherein λ2-λ1 is at least 20 nm;
at least one second green-yellow LED configured to emit third light having a third dominant peak wavelength, λ3, in the wavelength range from 500 nm to 595 nm, the third dominant peak wavelength, λ3, being different from the second dominant peak wavelength, λ2, wherein λ3-λ2 is at least 20 nm;
a plurality of first red-orange LEDs configured to emit fourth light having a fourth dominant peak wavelength, λ4, in a wavelength range from 600 nm to 695 nm, the fourth dominant peak wavelength, λ4, being different from the third dominant peak wavelength, λ3, wherein λ4-λ3 is at least 20 nm; and wherein the LED filament further comprises one or both of:
at least one third green-yellow LED configured to emit fifth light having a fifth dominant peak wavelength, λ5, in the wavelength range from 500 nm to 595 nm, the fifth dominant peak wavelength, λ5, being different from the second and third dominant peak wavelength, λ2 and λ3; and
at least one second red-orange LED configured to emit sixth light having a sixth dominant peak wavelength, λ6, in the wavelength range from 600 nm to 695 nm, the sixth dominant peak wavelength, λ6, being different from the fourth dominant peak wavelength, λ4.

The LED filament comprises at least ten LEDs arranged on an elongated carrier. The LED filament comprise a plurality of blue LEDs, a plurality of green-yellow LEDs and a plurality of red-orange LEDs arranged on the carrier. The proposed ratio in LED bins provides a high-quality LED filament light result even at a low luminous flex level.

Even when emitting an extreme warm white LED filament light. The LEDs arranged on the carrier are configured to provide a high-quality LED filament light when comprising more than five different dominant peak wavelengths. At least one of the five different dominant peak wavelengths are arranged in the wavelength range from 430 nm to 495 nm. The plurality of first blue LEDs is configured to emit first light having the first dominant peak wavelength, λ1, in the wavelength range from 430 nm to 495 nm.

At least two of the five different dominant peak wavelengths are arranged in the wavelength range from 500 nm to 595 nm. The plurality of first green-yellow LEDs configured to emit second light having a second dominant peak wavelength, λ2, in a wavelength range from 500 nm to 595 nm. The second dominant peak wavelength, λ2, is different from first dominant peak wavelength, λ1, having a difference of at least 20 nm. The at least one second green-yellow LED is configured to emit third light having a third dominant peak wavelength, λ3, in the wavelength range from 500 nm to 595 nm. The third dominant peak wavelength, λ3, is different from the second dominant peak wavelength, λ2, having a difference of at least 20 nm. The at least one third green-yellow LED is configured to emit fifth light having a fifth dominant peak wavelength, λ5, in the wavelength range from 500 nm to 595 nm. The fifth dominant peak wavelength, λ5, is different from the second and third dominant peak wavelength, λ2 and λ3.

At least one of the five different dominant peak wavelengths are arranged in the wavelength range from 600 nm to 695 nm. The plurality of first red-orange LEDs is configured to emit fourth light having a fourth dominant peak wavelength, λ4, in a wavelength range from 600 nm to 695 nm. The fourth dominant peak wavelength, λ4, is different from the third dominant peak wavelength, λ3, having a difference of at least 20 nm. Alternative, the at least one second red-orange LED configured to emit sixth light having a sixth dominant peak wavelength, λ6, in the wavelength range from 600 nm to 695 nm. The sixth dominant peak wavelength, λ6, is different from the fourth dominant peak wavelength, λ4.

By combining the LEDs, which provides at least five dominant peak wavelengths, as described above a white light is emitted. Due to the spectral overlap between the LEDs bandwidth such that the wavelengths represented are correlated. Each dominant peak wavelength may be chosen relatively to obtain a high Ra value.

Thereby, the need for a phosphor to convert light is removed. Thus, a phosphor-free LED filament capable of emitting a high-quality white light, preferably extreme warm white light is obtained. By further controlling the colored light of the various LEDs individually, as will also be described further below, a LED filament capable of emitting high-quality colored light may further obtained.

Thus, a phosphor-free LED filament with which a yellow/orange appearance similar to that of pc-LED filaments is avoided, and with which unwanted cross-talk of LED light and phosphor is also avoided, is provided. The phosphor-free LED filament provides a white-silver-looking appearance, which better resembles a filament of an incandescent lamp, which is desired.

In an embodiment following applies:
λ5-λ3 is at least 20 nm, λ5-λ2 is at least 20 nm, λ5-λ1 is at least 20 nm, and 26-24 is at least 20 nm.

The third green-yellow LED may be configured to emit fifth light having a fifth dominant peak wavelength, λ5, in the wavelength range from 500 nm to 595 nm. The fifth dominant peak wavelength, λ5 may be different from the first dominant peak wavelength, λ1, with a difference of at least 20 nm between λ5-λ1. The fifth dominant peak wavelength, λ5 may be different from the second λ2, with a difference of at least 20 nm between λ5-λ2. The fifth dominant peak wavelength, λ5 may be different from the third dominant peak wavelength, λ3, with a difference of at least 20 nm between λ5-λ2.

In an embodiment LED filament may further comprises at least one third red-orange LED configured to emit seventh light having a seventh dominant peak wavelength, λ7, in the wavelength range from 600 nm to 695 nm, the seventh dominant peak wavelength, λ7, being different from the fourth and sixth dominant peak wavelength, λ4 and λ6, with λ7-λ4 being at least 20 nm and with λ7-λ6 being at least 20 nm.

The third red-orange LED may be configured to emit seventh light having the seventh dominant peak wavelength, λ7, in the wavelength range from 600 nm to 695 nm. The seventh dominant peak wavelength, λ7, may be different from the fourth dominant peak wavelength, λ4, with a difference of at least 20 nm between λ7-λ4. The seventh dominant peak wavelength, λ7, may be different from the sixth dominant peak wavelength, λ6, with a difference of at least 20 nm between λ7-26.

In an embodiment the LED filament may further comprises at least one second blue LED configured to emit eighth light having an eighth dominant peak wavelength, λ8, in the wavelength range from 430 nm to 495 nm, the eighth dominant peak wavelength, λ8, being different from the first dominant peak wavelength, λ1, with λ1-λ8 being at least 20 nm. The second blue LED may be configured to emit eighth light having an eighth dominant peak wavelength, λ8, in the wavelength range from 430 nm to 495 nm. The eighth dominant peak wavelength, λ8, may be different from the first dominant peak wavelength, λ1, with a difference of at least 20 nm between λ8-λ1.

The above embodiments each further improve at least one of the qualities of the white light, preferably extreme warm white light, emitted by the LED filament, and the quality of the colored light emitted by the LED filament.

In an embodiment the LED filament may further comprise:
at least a first circuitry array comprising the plurality of first blue LEDs and, where present, the at least one second blue LED, and
at least a second circuitry array comprising the plurality of first green-yellow LEDs, the plurality of second green-yellow LEDs and, where present, the at least one third green-yellow LED, and
at least a third circuitry array comprising the plurality of first red-orange LEDs and, where present, the at least one second red-orange LED and the at least one third red-orange LED,
wherein each of the circuitry arrays are individually controllable.

The first circuitry array may comprise the plurality of first blue LEDs. The first circuitry array may furthermore comprise at least one second blue LED. Alternatively, a further first circuitry array may comprise the at least one second blue LED, such that the second blue LED or LEDs may be controlled independently of the first blue LEDs.

The second circuitry array comprise the plurality of first green-yellow LEDs. The second circuitry may furthermore comprise the plurality of second green-yellow LEDs. Alternatively, a further second circuitry may comprise the at least one third green-yellow LED. Each one of the first, second and third green-yellow LEDs may be connected to each of a second circuitry such that the green-yellow LEDs may be controlled independently of each other.

The third circuitry array comprising the plurality of first red-orange LEDs. The third circuitry may furthermore comprise the at least one second red-orange LED. Alternatively, a further third circuitry may comprise the at least one second red-orange LED. Alternatively, the third circuitry or the further third circuitry may comprise the at least one third red-orange LED. Each one of the first, second and third red-orange LEDs may be connected to each of a third circuitry, such that the green-yellow LEDs may be controlled independently of each other.

Each of the first, second and third circuitry and the further first, second and third circuitries arrays may be individually controlled, such that LEDs related to each of the dominant peak wavelength may be controlled independently of each other.

In an embodiment the LED filament comprises one or more of the following:
a number of green-yellow LEDs being at least 2 times a number of blue LEDs,
a number of red-orange LEDs being at least 4 times the number of blue LEDs, and
a number of red-orange LEDs being at least 2 times the number of green-yellow LEDs.

For further improved appearance a low luminous flux a number of green-yellow LEDs being at least 2 times a number of blue LEDs and a number of red-orange LEDs being at least 4 times the number of blue LEDs may be provided. Alternatively, the number of red-orange LEDs being at least 2 times the number of green-yellow LEDs.

Preferably, the number of red-orange LEDs may be larger than the numbers of blue LEDs and green-yellow LEDs together. More preferably, the number of red-orange LEDs may be at least twice the number of blue LEDs and green-yellow LEDs together.

In an embodiment the different LEDs related to each circuitry array is alternately positioned between each other along the carrier.

The different LEDs related to each circuitry array may be alternately positioned between each other along the carrier. Such a specific placement of each of the different LEDs provides a uniform filament look during use even at a low luminous flex level.

In an embodiment the one or more of the following applies: each of the blue LEDs is arranged between at least two of the red-orange LEDs, and each of the green-yellow LEDs is arranged between at least two of the red-orange LEDs.

Each of the blue LEDs is arranged between at least two of the red-orange LEDs, positioned between each other along the carrier. Each of the green-yellow LEDs is arranged between at least two of the red-orange LEDs positioned between each other along the carrier.

Such a specific placement of each of the blue LEDs and the green-yellow LEDs separated by at least one red-orange LED provides a uniform filament look during use even at a low luminous flex level.

In an embodiment the LED filament further comprises an array of LEDs arranged in the following order of:
a first blue LED configured to emit a first dominant peak wavelength λ1,
a first red-orange LED configured to emit a fourth dominant peak wavelength λ4,
a second green-yellow LED configured to emit a third dominant peak wavelength λ3,
a second red-orange LED configured to emit a sixth dominant peak wavelength λ6,
followed by:
a first blue LED configured to emit a first dominant peak wavelength λ1,
a first red-orange LED configured to emit a fourth dominant peak wavelength λ4,
a first green-yellow LED configured to emit a second dominant peak wavelength λ2,
a second red-orange LED configured to emit a seventh dominant peak wavelength λ7.

A plurality of LEDs may be arranged in an array on the carrier in a first predetermined order. The plurality of LEDs may be controlled individually or in groups using a plurality of controllable circuitry arrays provided on or in the carrier. A plurality of first blue LEDs and a plurality of first and second green-yellow LEDs are arranged alternately along the carrier. A plurality of first, second and third red-orange LEDs are alternatively placed between the first blue LEDs and a plurality of first and second green-yellow LEDs such that every second LED is a first, second or third red-orange LED. In one example, wherein the array of LEDs is in the following order of a first blue LED emitting a first dominant peak wavelength λ1, a first red-orange LED emitting a fourth dominant peak wavelength λ4, a second green-yellow LED emitting a third dominant peak wavelength λ3, a second red-orange LED emitting a sixth dominant peak wavelength λ6, followed by a first blue LED emitting a first dominant peak wavelength λ1, a first red-orange LED emitting a fourth dominant peak wavelength λ4, a first green-yellow LED emitting a second dominant peak wavelength λ2, a second red-orange LED emitting a seventh dominant peak wavelength λ7. The order of LEDs may be repeatedly arranged along the carrier. If a plurality of second blue LEDs is provided and if a plurality of green-yellow LEDs is provided, the first predetermined order may be arranged accordingly to the LEDs provided. Such a specific placement of each of the LEDs mentioned above provides for a particularly uniform filament look during use even at a low luminous flex level, and with a particularly high-quality LED filament light.

In an embodiment the LED filament further comprises an array of LEDs arranged in the following order of:
a first blue LED configured to emit a first dominant peak wavelength λ1,
a first red-orange LED configured to emit a fourth dominant peak wavelength λ4,
a first green-yellow LED configured to emit a third dominant peak wavelength λ2,
a second red-orange LED configured to emit a sixth dominant peak wavelength λ6,
followed by:
a first blue LED configured to emit a first dominant peak wavelength λ1,
a first red-orange LED configured to emit a fourth dominant peak wavelength λ4, a second green-yellow LED configured to emit a second dominant peak wavelength λ3, a second red-orange LED configured to emit a seventh dominant peak wavelength 27.

Alternatively, the plurality of LEDs may be arranged in an array on the carrier in a second predetermined order. The array of LEDs may be arranged in the following order of a first blue LED emitting a first dominant peak wavelength λ1, a first red-orange LED emitting a fourth dominant peak wavelength λ4, a first green-yellow LED emitting a third dominant peak wavelength λ2, a second red-orange LED emitting a sixth dominant peak wavelength λ6, followed by a first blue LED emitting a first dominant peak wavelength λ1, a first red-orange LED emitting a fourth dominant peak wavelength λ4, a second green-yellow LED emitting a second dominant peak wavelength λ3, a second red-orange LED emitting a seventh dominant peak wavelength λ7. The order of LEDs may be repeatedly arranged along the carrier or repeatedly arranged alternately with the first predefined order. If a plurality of second blue LEDs is provided and if a plurality of green-yellow LEDs is provided, the second predetermined order is arranged accordingly to the LEDs provided. Such a specific placement of each of the LEDs mentioned above provides for a particularly uniform filament look during use even at a low luminous flex level, and with a particularly high-quality LED filament light.

In an embodiment the LED filament further comprises an encapsulant, wherein the encapsulant covers the LEDs, and wherein the encapsulant covers the elongated carrier comprising the LEDs fully or partially.

The LED filament may further comprise an encapsulant, wherein the encapsulant covers the LEDs to ensure the LED filament light passes through the encapsulant. The encapsulant covers the elongated carrier fully or partially. The carrier may be transparent. The carrier may be flexible.

In an embodiment the encapsulant comprises a light scattering material or wherein the encapsulant is transparent.

The encapsulant may comprises a light scattering material. The light scattering material, e.g., TiO2 particles or similar, may be provided to scatter and mix the LED filament light. Alternatively, the encapsulant may be transparent.

In an embodiment the LED filament may be configured to emit white light from the LED filament, the white light having a color rendering index of at least 85 capable of varying between a first CCT and a second CCT, wherein the difference between first CCT and second CCT is at least 1000K, or the difference between first CCT and second CCT is at least 2000K, or wherein CCT1≤2500K and CCT2≥3000K.

The LED filament may be configured to emit white light having a color rendering index of at least 80, preferable 85 or more. For example, the LED filament may be configured to emit white light having a CCT in a range from 1800K to 2400K with a color rendering index of at least 85. The white light emitting from the LED filament may be capable of varied during use, such that the CCT, may be varied between a first CCT and a second CCT. The difference between first CCT and second CCT may be at least 1000K. Alternative, the difference between first CCT and second CCT may be at least 2000K. The first CCT may be less or equal to 2500K and the second CCT may be higher or equal to 3000K.

In an embodiment the LED filament is phosphor-free. The LED filament may provide a full-spectrum LED filament light. The LED filament may be provided the light during operation using a direct-emitting LEDs free from a phosphor cover, such that no phosphor is present in the LED filament. The LED filament is provided with a plurality of different LEDs having different dominant peak wavelengths. The light emitting from the plurality of different LEDs may correlate such that the light comprises a spectral overlap between the light emitting from the plurality of different LEDs and thereby providing a full-spectrum white light or substantially a full-spectrum white light. Alternatively, plurality of different LEDs may be selected relative to the measurement of the color rending index, CRI, such that the CRI is more than 80, preferably more than 85.

In a second aspect of the invention, a LED filament arrangement further comprises a controller configured to control LED filament light emitted from at least one LED filament, and wherein the controller is configured to control each circuitry array individually.

The LED filament arrangement comprises a controller. The controller is configured to control the luminous flux of the light emitting from each of the LEDs arranged on the LED filament or LED filaments. The controller is configured to control each circuitry array individually, such that the controller controls LED filament light emitted from at least one LED filament during operation. The controller may be in data communication with an external control system. LED filament capable of emitting a colored light, wherein the colored light can be individually controlled, such as to be capable of meeting specific requirements, e.g., the PHILIPS HUE requirements.

During operation, the controller may control the luminous flux of the first light emitting plurality of first blue LEDs and the luminous flux of the eighth light emitting plurality of second blue LEDs together using common circuitry array or individually using separately circuitry arrays. During operation, the controller may also control the luminous flux of the second light emitting plurality of first green-yellow LEDs LEDs and the luminous flux of the third light emitting plurality of second green-yellow LEDs, and when provided the luminous flux of the fifth light emitting plurality of third green-yellow LEDs, together using common circuitry array or individually using separately circuitry arrays. During operation, the controller may control the luminous flux of the fourth light emitting plurality of first red-orange LEDs and the luminous flux of the sixth light emitting plurality of second red LEDs together using common circuitry array or individually using separately circuitry arrays, etc.

The controller is configured to during use, controlling a white LED filament light emitting from the LED filament, such that the white light has a color rendering index of at least 80, preferably at least 85. The controller may during use furthermore be capable of controlling the white LED filament light emitting from the LED filament, such that the white light can be varied between a first CCT and a second CCT. The controller may during use be capable of controlling the white LED filament light emitting from the LED filament, such that the white light has a difference between first CCT and second CCT is at least 1000K.

Alternatively, the controller may during use be capable of controlling the white LED filament light emitting from the LED filament, such that the difference between first CCT and second CCT is at least 2000K. The controller may during use be capable of controlling the white LED filament light emitting from the LED filament, such that the white light emitting from the filament may be CCT1≤2500K and CCT2≥3000K.

The invention further relates to a LED filament lamp comprising at least one LED filament or a LED filament arrangement comprising at least one LED filament, wherein said LED filament is at least partly enclosed by a light-transmissive envelope, and wherein the LED filament lamp comprises a base configured to be mechanically and electrically connected to a socket in a luminaire or luminaire system.

The LED filament lamp comprises at least one LED filament at least partly enclosed by a light-transmissive envelope. The LED filament lamp may comprise a base. The LED filament may be configured to be mechanically and electrically connected to the base.

The LED filament lamp may comprise a base configured to be mechanically and electrically connected to a socket in a luminaire or luminaire system. LED filament lamp may comprise a LED filament arrangement comprising at least one LED filament and a controller. The LED filament may be configured to be mechanically and electrically connected to the controller. The controller may be configured to be mechanically and electrically connected to the base.

### BRIEF DESCRIPTION OF THE DRAWINGS

This and other aspects of the present invention will now be described in more detail, with reference to the appended drawings showing embodiment(s) of the invention.

FIG. 1 illustrates a LED filament arranged in a LED filament lamp shaped as a traditional lamp or light bulb seen in a cross-sectional side view.

FIG. 2 shows a spectral power distribution of LEDs having different dominant peak wavelengths.

FIG. 3 shows a plurality of LEDs arranged in an array on an elongated carrier seen in a schematical top view.

Like reference numerals refer to like elements throughout.

### DETAILED DESCRIPTION

The present invention will now be described more fully hereinafter with reference to the accompanying drawings, in which currently preferred embodiments of the invention are shown. This invention may, however, be embodied in many different forms and should not be construed as limited to the embodiments set forth herein; rather, these embodiments are provided for thoroughness and completeness, and fully convey the scope of the invention to the skilled person.

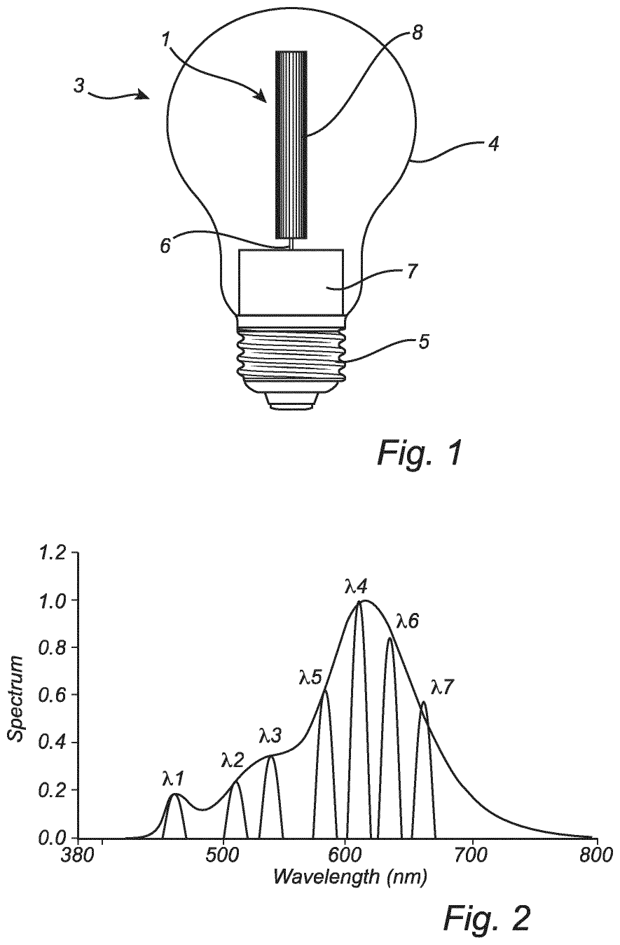

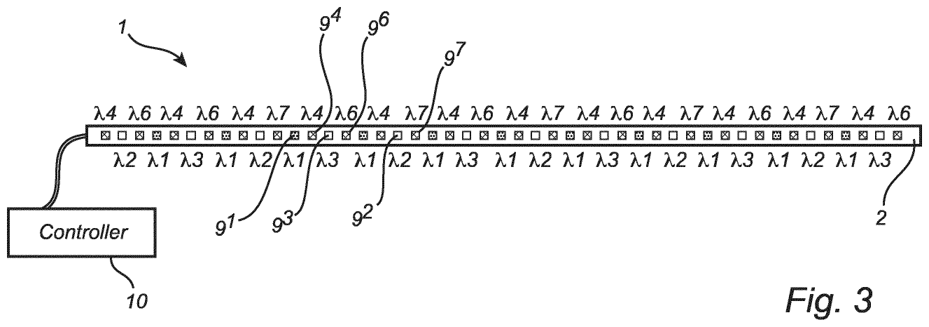

FIG. 1 illustrates a cross-sectional view of a LED filament 1 arranged in a LED filament lamp 3 shaped as a traditional lamp. The LED filament lamp 3 may be differently shaped according to a specific application. The LED filament 1 is, during use, emitting a controllable LED filament light. The LED filament lamp 3 comprises at least one LED filament enclosed by a light-transmissive envelope 4 and a base 5. The base 5 is capable of being mechanically and electrically connected to a socket in a luminaire or luminaire system. LED filament lamp 3 comprises a LED filament arrangement having an elongated LED filament 1 and a controller 7. The controller 7 is arranged between the LED filament 1 and the base 5. The LED filament 1 is in one end connected 6 mechanically and electrically to the controller 7. The LED filament 1 extends away from the base 5 of the LED filament lamp 3. The controller 7 is mechanically and electrically connected to the base 6. LED filament 1 comprises an encapsulant 8. The encapsulant 8 covers the elongated carrier fully or partially. Referring also to FIG. 3, the elongated LED filament 1 comprises a plurality of colored LEDs 9¹-9ⁿ arranged on an elongated carrier 2. The elongated carrier 2 may for instance be a printed circuit board, PCB. Although not visible on the figures, the elongated carrier 2 may comprise circuitry or circuitry arrays connected to the plurality of colored LEDs 9¹-9ⁿ and configured to provide the plurality of colored LEDs 9¹-9ⁿ with electrical energy in a manner to be described in further detail below. The LED filament 1 comprises at least ten LEDs 9¹-9ⁿ

FIG. 2 illustrates a spectral power distribution over the visible spectrum of a white light emitted from a plurality of LEDs 9¹-9ⁿ having different dominant peak wavelengths of a LED filament 1 according to the invention. The spectral power distribution of the light emitting from the LED filament 1 depends on the amount of light emitting form each of the LEDs presented in the LED filament.

The white light may comprise light emitted from a plurality of first blue LEDs configured to emit first light having a first dominant peak wavelength λ1 in a wavelength range from 430 nm to 495 nm. The white light may also comprise light emitted from a plurality of first and second green-yellow LEDs configured to emit second light having a second and third dominant peak wavelengths λ2, λ3. The second and third dominant peak wavelengths, λ2, λ3 is in the wavelength range from 500 nm to 595 nm. The second dominant peak wavelength λ2 is different from first dominant peak wavelength λ1 with at least 20 nm. The third dominant peak wavelength λ3 is different from second dominant peak wavelength λ2 with at least 20 nm. The white light may also comprise light emitted from at least one third green-yellow LED configured to emit fifth light having a fifth dominant peak wavelength λ5 in the wavelength range from 500 nm to 595 nm. The fifth dominant peak wavelength λ5 may be different from the third dominant peak wavelength λ3 with at least 20 nm to the nearest dominant peak wavelength. The white light may further comprise light from a plurality of first red-orange LEDs configured to emit fourth light having a fourth dominant peak wavelength λ4 in a wavelength range from 600 nm to 695 nm. The fourth dominant peak wavelength λ4 is in this example different from the fifth dominant peak wavelength λ5 with at least 20 nm, as illustrated on FIG. 2. The white light may also comprise light emitting from at least one second and third red-orange LED configured to emit sixth and seventh light having a sixth and seventh dominant peak wavelength λ6, λ7 in the wavelength range from 600 nm to 695 nm. The sixth dominant peak wavelength λ6 may be different from the fourth and the seventh dominant peak wavelength, λ4, λ7 with at least 20 nm to the nearest dominant peak wavelengths.

A first circuitry array may electrically connect the plurality of first blue LEDs configured to emit a first bluish light having a first dominant peak wavelength λ1, such that the light emitting from the first blue LEDs may be controlled separately from the green-yellow LEDs and the red-orange LEDs. The first dominant peak wavelength λ1 is in the bluish wavelength range from 430 nm to 495 nm.

A second circuitry array may electrically connect a plurality of first green-yellow LEDs and a plurality of second green-yellow LEDs. Alternatively, two second circuitry array may each electrically connect a plurality of first green-yellow LEDs and a plurality of second green-yellow LEDs, respectively, such that the light emitted from each of the first green-yellow LEDs and the second green-yellow LEDs may be controlled separately. A further second circuitry array may electrically connect a third green-yellow LED emitting a third greenish-yellowish light having a fifth dominant peak wavelength λ5. The light emitting from third green-yellow LED may be controlled separately from each of the first green-yellow LEDs and the second green-yellow LEDs or together with the first green-yellow LEDs and the second green-yellow LEDs.

At least one third circuitry array may electrically connect a plurality of first, second and third red-orange LEDs configured to emit a first reddish-orangish light having a fourth, sixth and seventh dominant peak wavelength λ4, λ6, λ7. The fourth, sixth and seventh dominant peak wavelength λ4, λ6, λ7 may all be in the reddish-orangish wavelength range from 600 nm to 695 nm, such that the light emitting from each of the first, second and third red-orange LEDs λ4, λ6, λ7 may be controlled together. Alternatively, at least two or three third circuitry arrays may each electrically connect a plurality of first, second and third red-orange LEDs λ4, λ6, λ7, such that the plurality of first, second and third red-orange LEDs λ4, λ6, λ7 may be controlled separately.

The LED filament arrangement may comprise a controller 10 configured to control the LED filament light emitted from the LED filament 1. The controller 10 is configured to control each circuitry array individually. When controlling the first, second and third circuitry array separately, the LED filament 1 emits a light capable of varying the spectral power distribution between a first CCT and a second CCT. The controller 10 and the controller 7 may be mutually separate controllers. Alternatively, the controller 10 and the controller 7 may be one and the same controller.

For example, the difference between the first CCT and the second CCT may be at least 1000K. Alternatively, the difference between first CCT and second CCT may be at least 2000K. The CCT1 may be equal or more than 2500K and CCT2 may be equal to or less than 3000K. The LED filament may be controlled such that the LED filament may emit white light having a color rendering index of at least 80, preferably more than 85.

FIG. 3 shows an example of a LED filament 1 according to the invention. In this example a plurality of LEDs 9¹-9ⁿ is arranged in an array on the elongated carrier 2. In this example, the plurality of LEDs is arranged in the first predefined order. The plurality of LEDs 9¹-9ⁿ shown in this example may be controlled individually or in groups by means of a plurality of controllable circuitry arrays provided on the carrier 2 and using a controller 7 or 10 as described above. A plurality of first blue LEDs 9¹ and a plurality of first and second green-yellow LEDs 9², 9³ are arranged alternately along the carrier 2. A plurality of first, second and third red-orange LEDs 9⁴, 9⁶, 9⁷ are alternatively placed between the first blue LEDs 9¹ and a plurality of first and second green-yellow LEDs 9², 9³ such that every second LED is a first, second or third red-orange LED 9⁴, 9⁶, 9⁷. For example as shown in this example, wherein the array of LEDs is in the following order of a first blue LED 9¹ emitting a first dominant peak wavelength λ1, a first red-orange LED 9⁴ emitting a fourth dominant peak wavelength λ4, a second green-yellow LED 9³ emitting a third dominant peak wavelength λ3, a second red-orange LED 9⁶ emitting a sixth dominant peak wavelength λ6, followed by a first blue LED 8¹ emitting a first dominant peak wavelength λ1, a first red-orange LED 9⁴ emitting a fourth dominant peak wavelength λ4, a first green-yellow LED 9² emitting a second dominant peak wavelength λ2, a second red-orange LED 9⁶ emitting a seventh dominant peak wavelength λ7. Each of the blue LEDs 9¹ is thereby arranged between at least two of the red-orange LEDs 9⁴, 9⁶, 9⁷, and each of the green-yellow LEDs 9², 9³ is arranged between at least two of the red-orange LEDs 9⁴, 9⁶, 9⁷. The order of LEDs is repeatedly arranged along the carrier 2.

The person skilled in the art realizes that the present invention by no means is limited to the preferred embodiments described above. On the contrary, many modifications and variations are possible within the scope of the appended claims.

Additionally, variations to the disclosed embodiments can be understood and effected by the skilled person in practicing the claimed invention, from a study of the drawings, the disclosure, and the appended claims. In the claims, the word “comprising” does not exclude other elements or steps, and the indefinite article “a” or “an” does not exclude a plurality. The mere fact that certain measures are recited in mutually different dependent claims does not indicate that a combination of these measured cannot be used to advantage.

1. A LED filament configured to emit LED filament light, wherein the LED filament comprises at least ten LEDs arranged on an elongated carrier wherein the LED filament comprises:
a plurality of first blue LEDs configured to emit first light having a first dominant peak wavelength, λ1, in a wavelength range from 430 nm to 495 nm;
a plurality of first green-yellow LEDs configured to emit second light having a second dominant peak wavelength, λ2, in a wavelength range from 500 nm to 595 nm, the second dominant peak wavelength, λ2, being different from first dominant peak wavelength, λ1, wherein λ2-λ1 is at least 20 nm;
at least one second green-yellow LED configured to emit third light having a third dominant peak wavelength, λ3, in the wavelength range from 500 nm to 595 nm, the third dominant peak wavelength, λ3, being different from the second dominant peak wavelength, λ2 wherein λ3-λ2 is at least 20 nm;
a plurality of first red-orange LEDs configured to emit fourth light having a fourth dominant peak wavelength, λ4, in a wavelength range from 600 nm to 695 nm, the fourth dominant peak wavelength, λ4, being different from the third dominant peak wavelength, λ3, wherein λ4-λ3 is at least 20 nm;
wherein the LED filament further comprises one or both of:
at least one third green-yellow LED configured to emit fifth light having a fifth dominant peak wavelength, λ5, in the wavelength range from 500 nm to 595 nm, the fifth dominant peak wavelength, λ5, being different from the second and third dominant peak wavelength, λ2 and λ3; and
at least one second red-orange LED configured to emit sixth light having a sixth dominant peak wavelength, λ6, in the wavelength range from 600 nm to 695 nm, the sixth dominant peak wavelength, λ6, being different from the fourth dominant peak wavelength, λ4,
wherein the following applies: λ5-λ3 is at least 20 nm, λ5-λ2 is at least 20 nm, λ5-λ1 is at least 20 nm, and λ6-λ4 is at least 20 nm, and
wherein LED filament further comprises:
at least one second blue LED configured to emit eighth light having an eighth dominant peak wavelength, λ8, in the wavelength range from 430 nm to 495 nm. the eighth dominant peak wavelength. λ8, being different from the first dominant peak wavelength, λ1. with λ1-λ8 being at least 20 nm.

2. LED filament according to claim 1, wherein LED filament further comprises at least one third red-orange LED configured to emit seventh light having a seventh dominant peak wavelength, λ7, in the wavelength range from 600 nm to 695 nm, the seventh dominant peak wavelength, λ7, being different from the fourth and sixth dominant peak wavelength, λ4 and λ6, with λ7-λ4 being at least 20 nm and with λ7-λ6 being at least 20 nm.

3. (canceled)

4. LED filament according to claim 1, wherein the LED filament further comprises:
at least a first circuitry array comprising the plurality of first blue LEDs and, where present, the at least one second blue LED, and
at least a second circuitry array comprising the plurality of first green-yellow LEDs the plurality of second green-yellow LEDs and, where present, the at least one third green-yellow LED, and
at least a third circuitry array comprising the plurality of first red-orange LEDs and, where present, the at least one second red-orange LED and the at least one third red-orange LED,
wherein each of the circuitry arrays are individually controllable.

5. LED filament according to claim 1, wherein the LED filament comprises one or more of the following:
a number of green-yellow LEDs being at least 2 times a number of blue LEDs,
a number of red-orange LEDs being at least 4 times the number of blue LEDs,
a number of red-orange LEDs being at least 2 times the number of green-yellow LEDS.

6. LED filament according to claim 1, wherein the different LEDs related to each circuitry array is alternately positioned between each other along the carrier.

7. LED filament according to claim 1, wherein one or more of the following applies: each of the blue LEDs is arranged between at least two of the red-orange LEDs, and each of the green-yellow LEDs is arranged between at least two of the red-orange LEDs.

8. LED filament according to claim 2, wherein the LED filament further comprises an array of LEDs arranged in one or more of the following order of:
configuration:
a first blue LED configured to emit a first dominant peak wavelength λ1,
a first red-orange LED configured to emit a fourth dominant peak wavelength λ4,
a second green-yellow LED configured to emit a third dominant peak wavelength λ3,
a second red-orange LED configured to emit a sixth dominant peak wavelength λ6,
followed by:
a first blue LED configured to emit a first dominant peak wavelength λ1,
a first red-orange LED configured to emit a fourth dominant peak wavelength λ4,
a first green-yellow LED configured to emit a second dominant peak wavelength λ2,
a second red-orange LED configured to emit a seventh dominant peak wavelength λ7;
configuration:
a first blue LED configured to emit a first dominant peak wavelength λ1,
a first red-orange LED configured to emit a fourth dominant peak wavelength λ4,
a second green-yellow LED configured to emit a third dominant peak wavelength λ2,
a second red-orange LED configured to emit a sixth dominant peak wavelength λ6,
followed by:
a first blue LED configured to emit a first dominant peak wavelength λ1,
a first red-orange LED configured to emit a fourth dominant peak wavelength λ4,
a first green-yellow LED configured to emit a second dominant peak wavelength λ3,
a second red-orange LED configured to emit a seventh dominant peak wavelength λ7.

9. LED filament according to claim 1, wherein the LED filament further comprises an encapsulant, wherein the encapsulant covers the LEDs, and wherein the encapsulant covers the elongated carrier comprising the LEDs fully or partially.

10. LED filament according to claim 9, wherein the encapsulant comprises a light scattering material or wherein the encapsulant is transparent.

11. LED filament according to claim 1, wherein the LED filament is configured to emit white light having a color rendering index of at least 85 capable of varying between a first CCT and a second CCT, wherein the difference between the first CCT and the second CCT is at least 1000K, or the difference between the first CCT and the second CCT is at least 2000K, and wherein CCT1≤2500K and CCT2≥3000K.

12. LED filament according to claim 1, wherein the LED filament is phosphor-free.

13. A LED filament arrangement comprising at least one LED filament according to claim 5, wherein the LED filament arrangement further comprises a controller configured to control LED filament light emitted from the at least one LED filament, and wherein the controller is configured to control each circuitry array individually.

14. LED filament lamp comprising at least one LED filament according to claim 1 or a LED filament arrangement-comprising at least one LED filament, wherein said LED filament is at least partly enclosed by a light-transmissive envelope, and wherein the LED filament lamp comprises a base configured to be mechanically and electrically connected to a socket in a luminaire or luminaire system.
